(19) United States
(12) Patent Application Publication
(10) Pub. No.: US 2005/0264140 A1
(43) Pub. Date: Dec. 1, 2005

(54) Piezoelectric oscillator and electronic device

(75) Inventor: Katsuhiko Miyazaki, Minowa-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/138,288

(22) Filed: May 27, 2005

(30) Foreign Application Priority Data
May 28, 2004 (JP) 2004-158519

(51) Int. Cl. H01L 41/053

(52) U.S. Cl. 310/344

(57) ABSTRACT

Exemplary embodiments of the invention provide a piezoelectric oscillator that enables reduction in thickness. A piezoelectric oscillator is configured to include: an electronic component electrically connected with one side face of a plurality of leads that are formed from a lead frame, a mold material that seals the electronic component such that the other side face of the plurality of leads is exposed, and a piezoelectric resonator element bonded to the other side face of the plurality of leads via a conductive material. Namely, a connection terminal is formed in the other side face of the plurality of leads. Moreover, the lead protruding from the mold material is bent downwards to form a mounting terminal.

### BACKGROUND

Exemplary embodiments of the present invention relate to a piezoelectric oscillator and an electronic device.

A piezoelectric oscillator is used in various electronic devices to obtain constant-frequency signals or the like in electronic circuits. Along with reduction in size of the electronic devices, the piezoelectric oscillator is also made thinner and is reduced in size. In FIG. 17, the sectional view of a piezoelectric oscillator according to related art is shown. A piezoelectric oscillator 200 according to the related art is configured by disposing, above and below, a circuit component 203 wherein an IC chip 201 is mounted on a lead frame 202 and the periphery of the IC chip 201 is covered with resin. The related art also includes a piezoelectric resonator 207 wherein a piezoelectric resonator element 204 is mounted on a ceramic package base 205, which is hermetic-sealed with a metallic lid body 206, and electrically and mechanically connecting the circuit component 203 with the piezoelectric resonator 207. See related art document Japanese Laid Open Patent Publication No. 2001-332932.

### SUMMARY

However, in the piezoelectric oscillator that is configured connecting, above and below, the piezoelectric resonator wherein the piezoelectric resonator element is mounted in the package, with the circuit component, there is a problem that it is not possible to make thinner by the amount of the thickness of the package base. Namely, the strength of the package base will decrease as the thickness of the ceramics forming the package base is made thinner. Therefore a problem exists that it is not possible to make thinner by the amount of the thickness of the package base because the ceramics requires the thickness for securing the strength.

Moreover, in the case where a piezoelectric oscillator is made a temperature-compensated piezoelectric oscillator, as a temperature sensor built in an IC chip is arranged closer to the piezoelectric resonator element, the temperature of the piezoelectric resonator element can be measured more accurately, and more precise temperature compensation can be made. However, because the distance between the temperature sensor and the piezoelectric resonator element becomes far due to the package base, there is a problem that more precise temperature compensation becomes difficult.

Furthermore, for the piezoelectric oscillator, a piezoelectric resonator and an IC chip are manufactured separately, and then only good ones are combined, however, when the piezoelectric resonator and the IC chip are combined, the oscillation frequency of the piezoelectric oscillator sometimes deviates from a reference frequency due to the variation of the load capacitance at an integrated circuit side. In this case, the oscillation frequency of the piezoelectric oscillator is adjusted by adjusting the capacitance at the IC chip side. However, in the case where the capacitance is adjusted with a capacitor array (a plurality of capacitors) which is provided in the IC chip, there is a problem that the oscillation frequency cannot be adjusted accurately because the IC chip size is restricted and thus, the number of the capacitors to be mounted in the IC chip is restricted.

Exemplary embodiments of the present invention have been made in order to address or solve the above-described and/or other problems. Exemplary embodiments provide a piezoelectric oscillator that enables reduction in thickness.

Moreover, exemplary embodiments of the present invention are intended to provide electronic devices wherein the piezoelectric oscillator that enables reduction in thickness is mounted.

In order to address or attain the above-described objectives, the piezoelectric oscillator according to exemplary embodiments of the present invention includes: a lead frame including a plurality of leads; an electronic component electrically connected with one side face of the plurality of leads; a mold material that seals the electronic component such that an other side face of the plurality of leads is exposed; a piezoelectric resonator element bonded to the other side face of the plurality of leads via a conductive material; and a lid body that hermetic-seals the piezoelectric resonator element. Because the piezoelectric resonator element is not housed in the package, the piezoelectric oscillator can be made thinner. Moreover, due to the fact that the piezoelectric oscillator has been made thinner, the distance between the piezoelectric resonator element and the electronic component becomes shorter, and thus the temperature difference between the piezoelectric resonator element and the electronic component can be reduced.

The piezoelectric oscillator according to exemplary embodiments includes: a lead frame including a plurality of leads; an electronic component electrically connected with one side face of the plurality of leads; a plurality of mounting terminals connected with a part of the plurality of leads, a level difference being formed on the electronic component side, a mold material that seals the electronic component such that an other side face of the plurality of leads and a mounting face of the plurality of mounting terminals are exposed; a piezoelectric resonator element bonded to the other side face of the lead via a conductive material; and a lid body that hermetic-seals the piezoelectric resonator element. The level difference is formed by bending the lead, half-etching the lead, or rolling the lead. Accordingly, because the piezoelectric oscillator is connected directly with the other side face side of the lead, the piezoelectric oscillator can be made thinner. Moreover, due to the fact that the piezoelectric oscillator has been made thinner, the distance between the piezoelectric resonator element and the electronic component becomes shorter, and thus the temperature difference between the piezoelectric resonator element and the electronic component can be reduced. Consequently, when the piezoelectric oscillator is made a temperature compensated type, the compensation of the frequency variation with respect to temperature can be made accurately.

Moreover, the mounting face of the mounting terminal and the surface of the electronic component are in the same face. Accordingly, because the surface of the resin package becomes the same face as the mounting face of the mounting terminal and the surface of the electronic component, the piezoelectric oscillator can be made thinner.

The piezoelectric oscillator according to exemplary embodiments includes: a lead frame including a plurality of leads; an electronic component electrically connected with one side face of the plurality of leads; a connection terminal connected with a part of the plurality of leads, a level difference being formed on the electronic component side; a mold material that seals the electronic component such that an other side face of the plurality of leads and a connection face of the connection terminal are exposed; a piezoelectric resonator element bonded to the connection face of the connection terminal via a conductive material; and a lid body that hermetic-seals the piezoelectric resonator element. The level difference is formed bending the lead, half-etching the lead, or rolling the lead. Accordingly, because the piezoelectric resonator element is directly connected with the connection terminal via the conductive material, the piezoelectric oscillator can be made thinner. Moreover, due to the fact that the piezoelectric oscillator has been made thinner, the distance between the piezoelectric resonator element and the electronic component becomes shorter, and thus the temperature difference between the piezoelectric resonator element and the electronic component can be reduced. Accordingly, when the piezoelectric oscillator is made a temperature compensation type, the compensation for the frequency variation with respect to temperature can be made accurately.

Moreover, the connection face of the connection terminal and the surface of the electronic component are in the same face. Accordingly, because the surface of a resin package becomes the same face as the connection face of the connection terminal and the surface of the electronic component, the piezoelectric oscillator can be made thinner.

The electrical connection of the electronic component with the lead, is carried out by flip-chip bonding. Because the electronic component can be face-down mounted on the lead, the piezoelectric oscillator can be made thinner.

The piezoelectric oscillator according to exemplary embodiments includes: a lead frame including a plurality of leads; an electronic component arranged in a space used to arrange the electronic component in the lead frame and electrically connected with one side face of the plurality of leads; a mold material that seals the electronic component such that an other side face of the plurality of leads is exposed; a piezoelectric resonator element bonded to the other side face side of the plurality of leads via a conductive material; and a lid body that hermetic-seals the piezoelectric resonator element. In this case, the connection terminal is prepared in the electronic component and is exposed from the mold material. Moreover, the mounting terminal is provided in the back face of the mold material, and the mounting terminal and lead are conducted by a hole (a via hole or a through-hole) that penetrates through this mold material from up to down. Accordingly, the piezoelectric oscillator can be reduced in size. Moreover, because the mounting terminal can be formed also in the portion of the back face of the resin package while vertically overlapping with the electronic component, the size of the mounting terminal can be enlarged and thus the joining strength with respect to the mounting substrate can be enhanced.

A moisture resistant material is applied to the surface of the mold material, the surface facing to the side where the piezoelectric resonator element is mounted. This moisture resistant material is applied at least on the molding resin. Accordingly, because moisture will not go through the package into the space where the piezoelectric resonator element is sealed, the piezoelectric resonator element can be hermetic-sealed. Then, because moisture will not attach to the piezoelectric resonator element and thus the oscillation frequency will not vary with time, the desired frequency can be obtained over a long period of time.

Moreover, a heat conducting material is provided in between the electronic component and the piezoelectric resonator element. Because there is provided a heat conducting material whose thermal conductivity is better than that of the molding resin of the resin package, the temperature of the piezoelectric resonator element side can be transmitted to the electronic component side. Accordingly, in the case where the piezoelectric oscillator is made a temperature compensation type, the temperature of the piezoelectric resonator element can be measured more accurately and temperature-compensated more accurately.

Moreover, the electronic device according to exemplary embodiments of the present invention includes the piezoelectric oscillator described above. Accordingly, the piezoelectric oscillator with the above-described properties can be mounted on electronic devices.

### BRIEF DESCRIPTION OF THE DRAWINGS

FIGS. 1(a)-(c) are schematics showing a piezoelectric oscillator according to a first exemplary embodiment;

FIG. 2 is a schematic showing a lead frame according to the first exemplary embodiment;

FIGS. 3(a)-(b) are schematics showing circuits to adjust the frequency;

FIG. 4 is a schematic showing a support device;

FIGS. 5(a)-(b) are schematics showing a piezoelectric oscillator provided with an adjustment terminal;

FIG. 6 is a schematic showing a piezoelectric oscillator wherein an electronic component for the frequency adjustment is mounted;

FIG. 7 is a schematic showing a piezoelectric oscillator wherein the periphery of a resin package is erected upwards so as to be formed;

FIGS. 8(a) and (b) are schematics showing the piezoelectric oscillator according to a second exemplary embodiment;

FIG. 9 is a schematic showing a lead frame according to the second exemplary embodiment;

FIG. 10 is a schematic showing a piezoelectric oscillator wherein a connection terminal is bend-formed;

FIG. 11 is a schematic showing the piezoelectric oscillator wherein a level difference is provided to a mounting-terminal forming lead;

FIGS. 12(a)-(b) are schematics showing the mounting-terminal forming lead according to an exemplary modification;

FIG. 13 is a schematic showing the piezoelectric oscillator according to a third exemplary embodiment;

FIGS. 14(a)-(e) are schematics showing manufacturing of the piezoelectric oscillator;

FIG. 15 is a schematic showing another exemplary embodiment of manufacturing the piezoelectric oscillator;

FIG. 16 is a schematic block diagram of a digital cellular phone; and

FIG. 17 is a schematic showing the piezoelectric oscillator according to the related art.

### DETAILED DESCRIPTION OF EMBODIMENTS

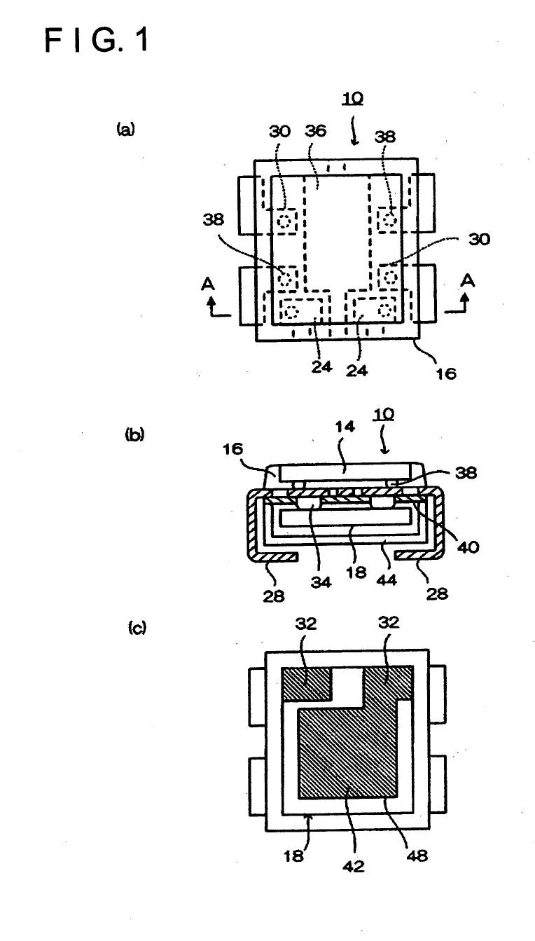

Hereinafter, exemplary embodiments of the piezoelectric oscillator and electronic devices according to exemplary embodiments of the present invention will be described. Note that, those to be described hereinafter are just one configuration of exemplary embodiments of the present invention, and the present invention is not restricted to these. First, a first exemplary embodiment is described. FIGS. 1(a)-(c) are schematics showing the piezoelectric oscillator according to the first exemplary embodiment. FIG. 1 (a) is a plane view of the piezoelectric oscillator, FIG. 1 (b) is a sectional view along the A-A line of FIG. 1 (a), and FIG. 1 (c) is a bottom plan view of the piezoelectric oscillator. Not that, in FIG. 1 (c), the description of a mounting terminal and a lid body is omitted. The piezoelectric oscillator 10 includes: an electronic component 14 electrically connected with one side face of a plurality of leads that are formed from a lead frame; a mold material that seals the electronic component 14 such that the other side face of the plurality of leads is exposed; and a piezoelectric resonator element 18 bonded to the other side face of the plurality of leads via a conductive material 34.

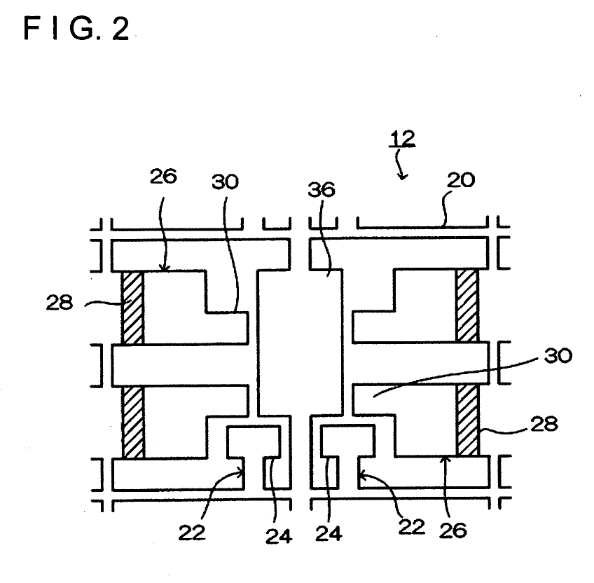

A plane view of a lead frame 12 is shown in FIG. 2. For the lead frame 12, a parallel-crosses shaped frame portion 20 is provided in a metal sheet having an electrical conductivity, such as an iron alloy or a copper alloy, and at the same time an identical pattern is formed in each frame portion 20. The lead includes a connection-terminal forming lead 22 of the piezoelectric oscillator 10 and a mounting-terminal forming lead 26. These connection-terminal forming lead 22 and mounting-terminal forming lead 26 are formed in the same face as that of the lead frame 12, without overlapping. The connection-terminal forming lead 22 forms a connection terminal 24 where the piezoelectric resonator element 18 is mounted and at least two leads 22 are provided. This connection-terminal forming lead 22 is connected with the inner side edge of the frame portion 20. Then, the connection terminal 24 is provided corresponding to the position of a connection electrode 32 provided in the piezoelectric resonator element 18, and at the same time it has such a size large enough to mount the piezoelectric resonator element 18 via a conductive material 34.

Moreover, the mounting-terminal forming lead 26 forms a terminal (a mounting terminal 28) for mounting the piezoelectric oscillator 10 on a mounting substrate. This mounting-terminal forming lead 26 is connected with the inner side edge of the frame portion 20. Then, the mounting-terminal forming lead 26 is provided extending to the position corresponding to the electrode that is formed in the electronic component 14, and at the tip thereof a terminal (a component connection terminal 30) for mounting the electronic component 14 is provided. This component connection terminal 30 is formed thinner than the other portion by forming a notch in the mounting-terminal forming lead 26 so as to reach the electrode of the electronic component 14 without contacting with the other lead. Moreover, because a mounting terminal 28 is formed in a wider portion of the mounting-terminal forming lead 26, the joining strength between the mounting terminal 28 and the mounting substrate can be secured.

Furthermore, in the center of the frame portion 20, a frame 36 for improving heat conduction between the piezoelectric resonator element 18 and the electronic component 14 is provided. This frame 36 serves as a heat conducting material, and is connected with the inner side edge of the frame portion 20.

On such connection-terminal forming lead 22 and mounting-terminal forming lead 26, the electronic component 14 is mounted via a conductive material 38. This electronic component 14 is a circuit to oscillate the piezoelectric resonator element 18, and serves as an IC chip. With respect to this circuit, a temperature compensation circuit and a voltage compensation circuit can be also added. In addition, the above circuit may be formed with a discrete circuit without making an IC chip. Then, the conductive material 38 is a bump-bonding material, and the electronic component 14 is flip-chip bonded on each lead. Accordingly, the electrode provided in the electronic component 14 are electrically and mechanically connected with the component connection terminal 30, and the electrode is electrically and mechanically connected with the connection terminal 24.

Then, the electronic component 14 is sealed in a resin package 16. Namely, the lead frame 12 where the electronic component 14 is mounted is placed in a resin molding tooling, and the resin package 16 is formed by injecting a thermosetting resin of an epoxy system or the like into this resin molding tooling. At this time, at least the principal face of the connection terminal 24, i.e. the connection face with which the piezoelectric resonator element 18 is connected, is exposed from the resin package 16. In order to expose the connection face of the connection terminal 24 to the surface of the resin package 16, the resin just needs to be injection-molded in the state that the connection face is caused to be in contact with the undersurface of the resin molding tooling. Incidentally, there may be cases where the resin intrudes in between the connection face of the connection terminal 24 and the resin molding tooling due to the injection pressure of the resin, and the resin adherers to the connection face. In this case, the adhered resin may be removed by spraying a liquid containing a polishing agent to the connection face. Moreover, a laser beam may be irradiated, or a chemical may be applied to the connection face to remove the adhered resin. Moreover, the mounting-terminal forming lead 26 exists in the bottom face of the resin package 16, and is protruding towards the resin package 16 side. The mounting terminal 28 is prepared in this protruding portion. In addition, the upper face of the electronic component 14 may be exposed to the surface of the resin package 16 (refer to FIG. 1 (b)), and may be sealed in the resin package 16.

Next, to the surface of the resin package 16 at the side where the piezoelectric resonator element 18 is mounted, a moisture resistant material 40, which is better in moisture resistance than the molding resin, is applied. This moisture resistant material 40 may be applied to the entire surface of the resin package 16 so that the connection face of the connection terminal 24 is exposed, or may be applied only to the portion where the molding resin is exposed from a gap between the leads. In addition, not only to the portion where the molding resin is exposed from the gap between the leads, the moisture resistant material 40 may be applied overlapping to the peripheral portion of the connection terminal 24. In this case, even if the applied position of the moisture resistant material 40 deviates to some extent, the place where the molding resin is exposed can be covered with the moisture resistant material 40, for certain. Moreover, as for the moisture resistant material 40, glass is used, for example, and the moisture resistant material 40 is selected suitably depending on the type of the piezoelectric resonator element 18. In addition, if glass is used, the piezoelectric resonator element 18 can be hermetic-sealed. Depending on the exemplary embodiment, the moisture resistant material 40 may not be applied to the package. In addition, the moisture resistant material 40 can also have a role as a bank reducing a conductive material 34 for connecting the piezoelectric resonator element 18 with the connection terminal 24 from flowing into additional places as will be described later.

Then, plating is applied to the connection face of the connection terminal 24, and to the principal face of the mounting terminal 28. The principal face of the mounting terminal 28 is the mounting face at the time of bonding the mounting terminal 28 to the mounting substrate. This plating is applied in order to enhance the adhesion between the connection face and the conductive material 34 at the time of bonding the piezoelectric resonator element 18 to the connection face, and the adhesion between the mounting face and the bonding material at the time of bonding the mounting face to the mounting substrate. As for this plating, nickel-plating or gold-plating may be applied, for example, by using an electric-field plating, or a solder plating may be also applied. In addition, as another configuration of the exemplary embodiment, the moisture resistant material 40 may be applied to the resin package 16 after having applied the plating to the connection face and the mounting face. In this case, the adhesion between the surface of the plating and the moisture resistant material 40 may be enhanced giving irregularities by applying a liquid containing an etcher and a polishing agent to the surface of the plating in the peripheral portion of the connection face in advance.

Subsequently, the connection-terminal forming lead 22, the mounting-terminal forming lead 26 and the frame 36 are cut off from the frame portion 20 of the lead frame 12. At this time, preferably the connection-terminal forming lead 22 and the frame 36 are cut along the outline of the resin package 16. Moreover, the mounting-terminal forming lead 26 is cut so as to protrude from the outline of the resin package 16. Accordingly, each lead is cut off from the frame portion 20, and is made into individual component.

Next, the piezoelectric resonator element 18 is mounted on the connection face of the connection terminal 24 via the conductive material 34. Although in FIG. 1, the piezoelectric resonator element 18 is mounted in a cantilever state, it may be mounted so as to be supported by both sides instead. For the piezoelectric resonator element 18, AT-cut piezoelectric resonator element 18 or the like which produces a thickness-shear mode vibration may be used. In this piezoelectric resonator element 18, an excitation electrode 42 is formed on both sides of a piezoelectric substrate 48 that is made of a piezoelectric material, and the connection electrode 32 is formed in the corner portion of the piezoelectric substrate 48 while conducting to each excitation electrode 42. In addition, in place of the piezoelectric resonator element 18, a tuning fork type piezoelectric resonator element that produces a bending vibration, or a surface-acoustic-wave (SAW) resonance piece that excites a surface acoustic wave can be also used. Moreover, as for the conductive material 34, material that can just connect electrically and mechanically the piezoelectric resonator element 18 with the connection terminal 24 may be used, and for example, a conductive adhesive can be used.

Subsequently, the frequency adjustment of the piezoelectric oscillator 10 is carried out changing the thickness of the excitation electrode 42 of the piezoelectric resonator element 18. The thickness adjustment of the excitation electrode 42 is carried out by shaving this excitation electrode 42 or by film-forming a metal to the excitation electrode 42. In the case where the frequency is adjusted by shaving the excitation electrode 42, the resin package 16 where the piezoelectric resonator element 18 is already mounted, is placed in a vacuum vessel to excite the piezoelectric resonator element 18. Then, while measuring the oscillation frequency during this excitation, an etching gas is introduced into the vacuum vessel to generate plasma, and the excitation electrode 42 is etched by exposure to this plasma. The etching is completed when having been close to a desired oscillation frequency. Namely, the oscillation frequency is driven to the desired oscillation frequency to some extent by etching in advance. In addition, other than the case where the excitation electrode 42 is shaved using plasma, it is also possible to etch using ions that are generated with an ion gun or the like. Moreover, it is also possible to shave the excitation electrode 42 by irradiating a laser beam to the excitation electrode 42. Incidentally, in the case where the frequency of the tuning fork type piezoelectric resonator element is adjusted, because a weight is provided at the tip of an oscillating arm, it is possible to adjust the frequency by shaving this weight. Moreover, in the case where the frequency of the SAW resonance piece is adjusted, because a bamboo-blind shaped electrode (IDT) is provided in the surface of the piezoelectric substrate 48, the frequency is adjusted shaving this IDT.

Moreover, in the case where the frequency is adjusted by film-forming a metal to the excitation electrode 42, a mask is provided above the piezoelectric resonator element 18 so that only the excitation electrode 42 may be exposed, and the resin package 16, where the piezoelectric resonator element 18 is mounted, is placed in a film forming equipment. Then, while measuring the oscillation frequency by exciting the piezoelectric resonator element 18, the metal is film-formed on the excitation electrode 42. The film-forming of the metal is completed when having been close to the desired oscillation frequency. Namely, the oscillation frequency is driven to the desired oscillation frequency to some extent by film-forming the metal in advance. In addition, as for the metal material to be film-formed, preferably the same material as the one forming the excitation electrode 42 is used to enhance adhesion to the excitation electrode 42.

After this frequency adjustment, a lid body 44 that hermetic-seals the piezoelectric resonator element 18 is bonded to the resin package 16. This lid body 44 is made of metal, glass, resin, or the like, and has a box shape wherein the periphery of a planar substrate is erected upwards so as to be formed. Then, the resin package 16, where the piezoelectric resonator element 18 is mounted, and the lid body 44 are placed in an airtight container, and the inside of the airtight container is vacuumed, or filled with an inert gas, such as nitrogen. Subsequently, the lid body 44 is bonded via a soldering material to the surface of the resin package 16 at the side where the piezoelectric resonator element 18 is mounted, and thereby the piezoelectric resonator element 18 is hermetic-sealed. The soldering material just needs to be a low melting glass, resin, or the like. Moreover, in the case where a glass is used as the moisture resistant material 40, this moisture resistant material 40 can be also used as the soldering material. Furthermore, in the case where resin is used as the material of the lid body 44, the moisture resistant material 40 may be applied to the inside of the lid body 44. This moisture resistant material 40 just needs to be a metal system, and the same material as the moisture resistant material 40 applied to the surface of the resin package 16 may be used.

Then, the mounting-terminal forming lead 26 is bent to form the mounting terminal 28. The bending direction is downwards of the piezoelectric oscillator 10. In FIG. 1, the piezoelectric resonator element 18 to be mounted in the piezoelectric oscillator 10 is directed downwards, and the mounting terminal 28 is formed on this piezoelectric resonator element 18 side. Depending on the exemplary embodiment, the electronic component 14 may be provided below the piezoelectric oscillator, and the mounting terminal 28 may be formed on this electronic component 14 side.

In addition, the width of the tip of the component connection terminal 30 that is formed in the mounting-terminal forming lead 26 may be enlarged like the connection terminal 24. Accordingly, the joining strength between the mounting-terminal forming lead 26 and the resin package 16 can be enhanced, and thus the mounting-terminal forming lead 26 can be reduced or prevented from coming loose from the resin package 16 at the time of bending the mounting-terminal forming lead 26.

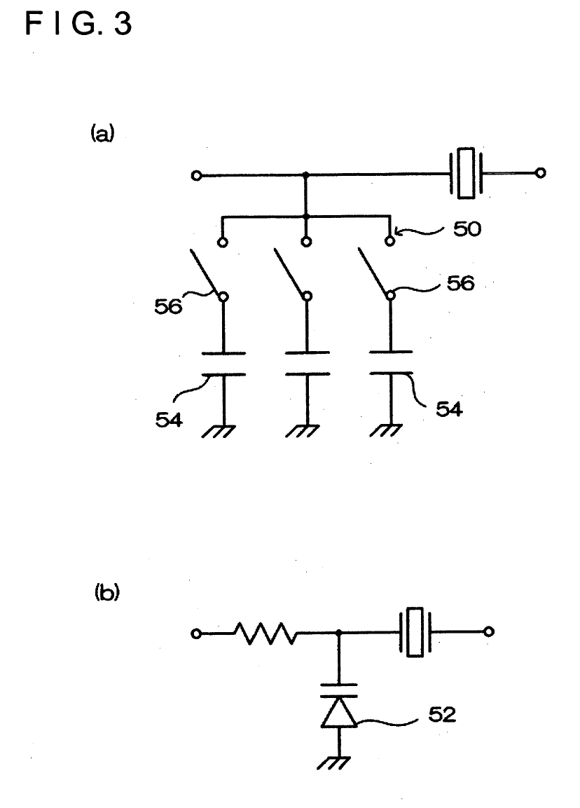

Next, the oscillation frequency of the piezoelectric oscillator 10 is adjusted once again. Because in the preceding process to seal the lid body 44, the oscillation frequency has been driven to some extent by adjusting the thickness of the excitation electrode 42, the oscillation frequency of the piezoelectric oscillator 10 is adjusted to the desired frequency in this step. This adjustment is made by the adjustment of capacitance of the capacitor array mounted in the electronic component 14 or by the adjustment of voltage supplied to the variable capacitance diode. FIGS. 3(a)-(b) are schematics showing a circuit where the frequency adjustment is made is shown. FIG. 3 (a) is an explanatory view of the capacitor array, and FIG. 3 (b) is an explanatory view of the circuit using the variable capacitance diode. In addition, although in FIG. 3 (a), a configuration using three capacitors is described, the number of capacitors is not restricted to this. In the case where the frequency is adjusted using a capacitor array 50 shown in FIG. 3 (a), the capacitor array 50 is provided in the electronic component 14, wherein a plurality of capacitors 54 having different capacitances are connected in parallel and a switch 56 is connected with each of these capacitors 54. Then, the writing to the electronic component 14 turns the switch 56 ON/OFF to adjust the load capacitance, thereby adjusting the oscillation frequency of the piezoelectric oscillator 10 to the desired frequency. Moreover, in the case where the frequency is adjusted by the circuit using the variable capacitance diode 52 as shown in FIG. 3 (b), this circuit is provided in the electronic component 14, and the capacitance is adjusted corresponding to the voltage supplied to the variable capacitance diode 52, thereby adjusting the oscillation frequency of the piezoelectric oscillator 10 to the desired frequency. Such adjustment is made by writing a program or the like to the electronic component 14.

In this way, because in the piezoelectric oscillator 10, the piezoelectric resonator element 18 is mounted via the conductive material 34 on the connection-terminal forming lead 22 that is formed from one sheet of lead frame 12, it is possible to make the oscillator thinner by the amount of the thickness of the ceramics that forms the package base. In addition, the thickness of the piezoelectric oscillator according to the related art, wherein the piezoelectric resonator element 18 is housed in the package is 1.0-1.2 mm, and the thickness of the bottom plate (ceramics) of the package base, is 0.15-0.2 mm. Accordingly, the thickness of the piezoelectric oscillator 10 according to this exemplary embodiment can be made thinner by at least 0.15-0.2 mm as compared with the piezoelectric oscillator according to the related art. Then, by the fact that the piezoelectric oscillator 10 has been made thinner, the distance between the piezoelectric resonator element 18 and the electronic component 14 becomes shorter, and thus the temperature difference between the piezoelectric resonator element 18 and the electronic component 14 can be reduced. Accordingly, when the piezoelectric oscillator 10 is made a temperature compensated type, compensation of the frequency variation due to temperature can be made accurately, and thus a frequency-temperature characteristic with a small frequency deviation can be obtained.

Moreover, the frequency adjustment of the piezoelectric oscillator 10 can be made adjusting the thickness of the excitation electrode 42 that is provided in the piezoelectric resonator element 18, in the state that the piezoelectric resonator element 18 is being mounted in the resin package 16. Then, the frequency adjustment of the piezoelectric oscillator 10 can be made adjusting the load capacitance at the electronic component 14 side, or by adjusting the voltage supplied to the variable capacitance diode 52. Namely, the frequency adjustment of the piezoelectric oscillator 10 is a two-step adjustment method of adjusting the load capacitance or the voltage at the electronic component 14 side after having adjusted the thickness of the excitation electrode 42 of the piezoelectric resonator element 18. Therefore, it is possible to reduce the frequency adjustment amount to the electronic component 14, enabling the reduction in size of the electronic component 14 and the reduction in size of the piezoelectric oscillator 10. Moreover, because only the capacitor array 50 capable of finely adjusting the oscillation frequency of the piezoelectric oscillator 10 can be mounted in the electronic component 14, the desired oscillation frequency can be obtained. In addition, depending on the exemplary embodiment, the frequency adjustment of the piezoelectric oscillator 10 may be made only by adjustment of the thickness of the excitation electrode 42.

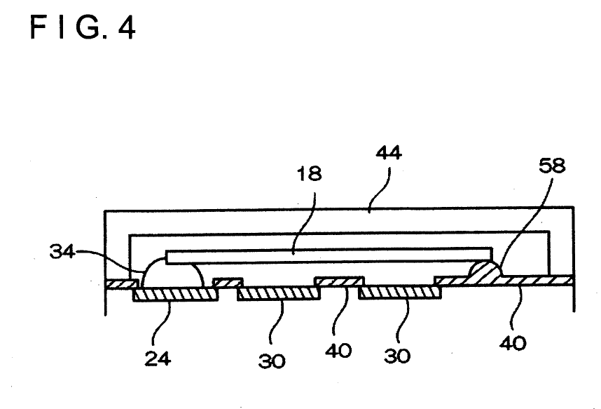

Moreover, in the case where the piezoelectric resonator element 18 to be mounted in the piezoelectric oscillator 10 is mounted in a cantilever state, if an impact due to dropping or the like is added to the piezoelectric oscillator 10, it is likely that the tip side of the piezoelectric resonator element 18 is swung greatly, colliding with the package. In order to reduce or prevent this piezoelectric resonator element 18 from being swung, a support means or the so-called bolster can be provided in the surface of the resin package 16 at the side where the piezoelectric resonator element 18 is mounted. An explanatory view of this support means is shown in FIG. 4. FIG. 4 is a schematic showing the case where a support device 58 is formed of the moisture resistant material 40. This support device 58 just needs to support the tip of the piezoelectric resonator element 18 by forming a protrusion with the moisture resistant material 40 or a molding resin at the tip side of the piezoelectric resonator element 18. Moreover, this protrusion may be formed of the lead and serve as the support device 58. Accordingly, even if an impact is added to the piezoelectric oscillator 10 due to dropping or the like, because the piezoelectric resonator element 18 is supported by the support device 58, it will not be swung greatly and thus cracking, breaking or the like will not occur in the piezoelectric resonator element 18. Consequently, the piezoelectric oscillator 10 having a high reliability can be obtained.

Although in the above-described exemplary embodiment, for the heat conducting material, a configuration using the frame 36 that is provided in the lead frame 12 has been described, a sheet having excellent heat conduction can also be used in place of this frame 36. This sheet just needs to be a material having a better heat conduction than the molding resin. Then, the sheet may be stuck to the electronic component 14, or can be sealed in the resin package 16 in between the electronic component 14 and the piezoelectric resonator element 18, and be provided in the piezoelectric oscillator 10. In addition, if the sheet is electric conductive, it will possibly have a capacitance between the excitation electrode 42 of the piezoelectric resonator element 18, and the sheet, depending on the exemplary embodiment. In this case, a non-conductive heat-conducting sheet may be used. Moreover, a configuration not using the heat conducting material may be employed depending on the exemplary embodiment.

Moreover, although the above-described piezoelectric oscillator 10 is configured connecting the electronic component 14 with the connection terminal 24 and component connection terminal 30 by flip-chip bonding, the electronic component 14 may be connected with the connection terminal 24 and component connection terminal 30 by wire bonding. In this case, the resin package 16 may be formed sealing the electronic component 14 and the wire.

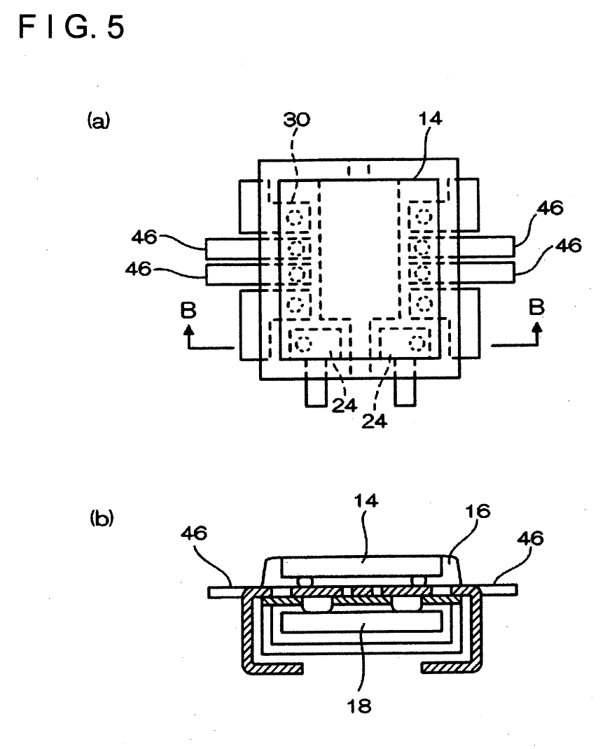

FIGS. 5(a)-(b) are schematics showing an explanatory view of a piezoelectric oscillator provided with an adjustment terminal. FIG. 5 (a) is a plane view, and FIG. 5 (b) is a sectional view along the B-B line of FIG. 5 (a). An adjustment terminal 46 can also be provided in the above-described piezoelectric oscillator 10. This adjustment terminal 46 is formed of a lead, which is to be connected with the lead frame 12, and flip-chip bonding or wire bonding is applied to the tip of this lead to connect with the electronic component 14. In addition, FIG. 5 shows a configuration where the flip-chip bonding is applied. Moreover, the connection-terminal forming lead can also be used as the adjustment terminal.

Then, the adjustment terminal 46 is used when writing a program in the electronic component 14, and other than this, it is used for carrying out the properties inspection and properties adjustment of the electronic component 14 and/or the conduction check between the piezoelectric resonator element 18 and the connection terminal 24. In addition, properties inspection refers to the operation check of the electronic component 14 after molding, and the properties inspection as the piezoelectric oscillator 10, and the like. Also, properties adjustment refers to correcting the frequency change due to the temperature of the piezoelectric oscillator 10 in the case where a temperature compensation circuit has been added to the electronic component 14, or refers to adjusting change sensitivity or the like in the case where a function for changing the frequency according to the input voltage has been added to the electronic component 14. In addition, the adjustment terminal 46 is to be cut at the outline position of the resin package 16 after the properties inspection or the like has been carried out.

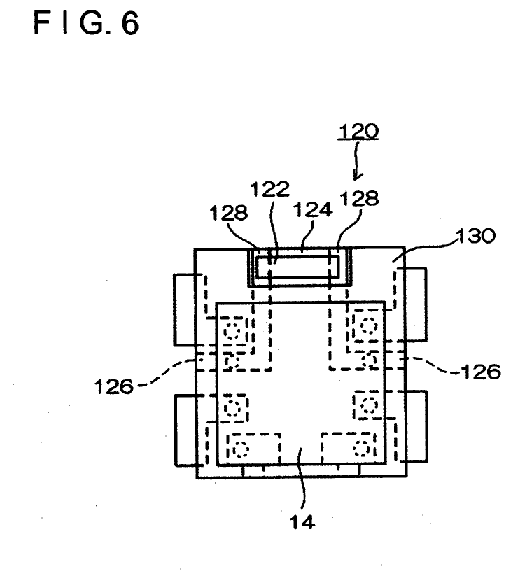

In FIG. 6, there is shown a plane view of a piezoelectric oscillator where an electronic component used for frequency adjustments is mounted. In the above-described embodiment, there has been described a method of adjusting the oscillation frequency of the piezoelectric oscillator 10 by adjusting the load capacitance or by adjusting the voltage supplied to the variable capacitance diode 52 at the electronic component 14 side. As a modification of the oscillation frequency adjustment of this piezoelectric oscillator, it is also possible to mount, on the piezoelectric oscillator, a component used for frequency adjustment such as a chip capacitor, and make the adjustment. Namely, a space 124 for mounting a frequency-adjustment component 122 to the piezoelectric oscillator 120, and a lead 126 causing this frequency-adjustment component 122 and the electronic component 14 to conduct just needs to be provided. An adjustment-component mounting terminal 128 is provided to the lead 126, and this terminal 128 just needs to be exposed from the molding resin so that the frequency-adjustment component 122 can be mounted after molding the resin package 130. For the frequency adjustment of this piezoelectric oscillator 120, the oscillation frequency of the piezoelectric oscillator 120 is measured first, and then a chip capacitor having the capacitance corresponding to the amount of the adjustments of the oscillation frequency just needs to be mounted on the adjustment-component mounting terminal 128 of the lead 126. In addition, the frequency-adjustment component 122 is mounted on the adjustment-component mounting terminal 128 via the conductive material, such as solder.

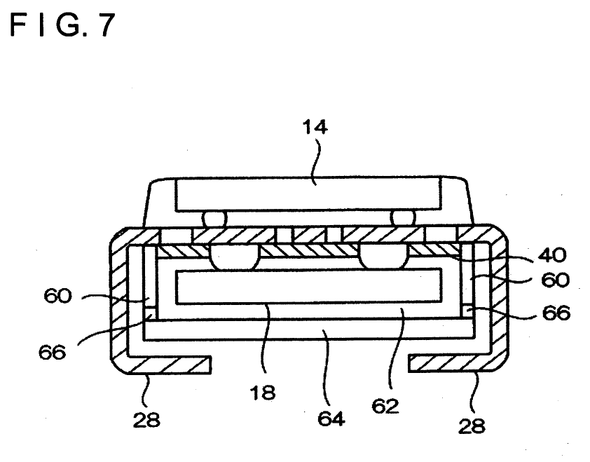

FIG. 7 is a schematic showing the piezoelectric oscillator 10 wherein the periphery of the resin package 16 is erected upwards so as to be formed. In the above-described exemplary embodiment, although the surface of the resin package 16 where the piezoelectric resonator element 18 is mounted is made planar, a side portion 60 may be formed erecting the periphery of the resin package 16 upwards to the piezoelectric resonator element 18 side, thereby forming a mold cavity 62 where the piezoelectric resonator element 18 is mounted, as shown in FIG. 7. In this case, a lid body 64 hermetic-sealing the mold cavity 62 just needs to be a planar substrate. Then, the lid body 64 is bonded to the upper face of the side portion 60 of the resin package 16 via a soldering material 66.

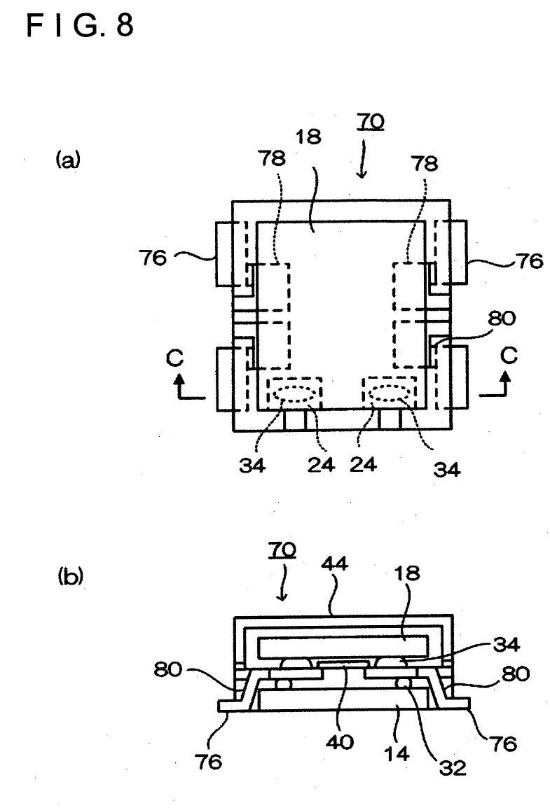

Next, a second exemplary embodiment will be described. In addition, the same numeral is given to the portion having the same configuration as that of the piezoelectric oscillator according to the first exemplary embodiment, and the description thereof will be omitted or simplified. FIGS. 8(a)-(b) are schematics showing the piezoelectric oscillator according to the second exemplary embodiment. FIG. 8 (a) is the plane view of the piezoelectric oscillator, and FIG. 8 (b) is the sectional view along the C-C line of FIG. 8 (a). A piezoelectric oscillator 70 is configured including: an electronic component 14 electrically connected with one side face of a plurality of leads that are formed from a lead frame; a plurality of mounting terminals 76 which are connected with a part of the plurality of leads and in which a level difference is formed on the electronic component side; a mold material (a molding resin) that seals the electronic component 14 such that the other side face of the plurality of leads and the mounting face of the plurality of mounting terminals 76 are exposed; and the piezoelectric resonator element 18 that is bonded via the conductive material 34 to the other side face of the lead, which is not connected with the mounting terminal 76.

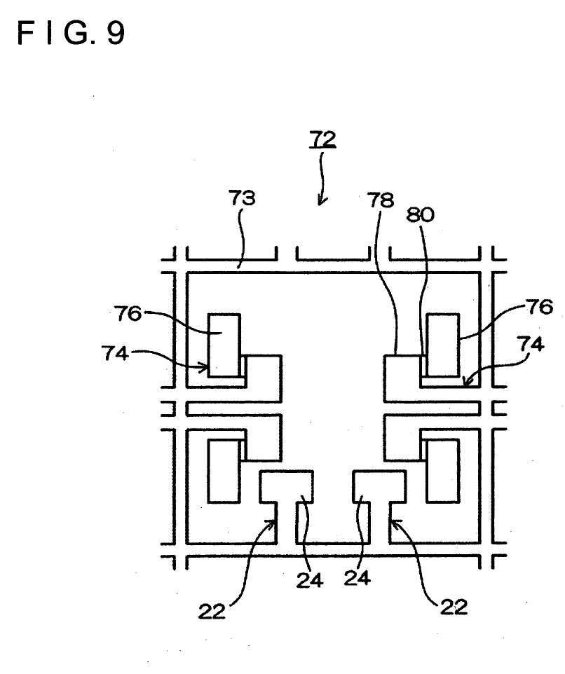

A plane view of a lead frame 72 is shown in FIG. 9. In the lead frame 72, there are provided the connection-terminal forming lead 22 and a mounting-terminal forming lead 74. The connection-terminal forming lead 22 is the same as that of the connection-terminal forming lead described in the first exemplary embodiment. Moreover, the mounting-terminal forming lead 74 is provided extending from the inner side edge of a frame portion 73 provided in the lead frame 72 to the electrode provided in the electronic component 14. At the tip thereof, there is provided a component connection terminal 78 that is formed wide-spreading. At the lead frame 72 side of this component connection terminal 78, an inclined portion 80 is provided in the portion which is not connected with the lead frame 72. At the lead frame 72 side of this inclined portion 80, the mounting terminal 76 is provided. Then, the inclined portion 80 is bent downward, and this bending causes to produce a level difference of the vertical direction in between the component connection terminal 78 and the mounting terminal 76.

Then, on the connection-terminal forming lead 22 and mounting-terminal forming lead 74, the electronic component 14 is mounted via the conductive material 38. This electronic component 14 is mounted on the side to which the inclined portion 80 is bent. At this time, the electrode provided in the electronic component 14 are electrically and mechanically connected with the component connection terminal 78, and the electrode is electrically and mechanically connected with the connection terminal 24. In addition, the surface of the electronic component 14, i.e., the opposite side of the electrode, is located in the same plane as the mounting face of the mounting terminal 76. Then, the periphery of the electronic component 14 is sealed with a molding resin to form the resin package 16. At this time, the mounting face of the mounting terminal 76 and the connection face of the connection terminal 24 are exposed to the surface of the resin package 16. Moreover, the side face of the mounting terminal 76 is exposed to the side face of the resin package 16. In the case where the side face of the mounting terminal 76 is exposed to the side face of the resin package 16, when the piezoelectric oscillator 70 is mounted to the mounting substrate via a bonding material, the bonding material not contained within the mounting face of the mounting terminal 76 follows the side face of the mounting terminal 76 upwards, and thereby a fillet is formed from the electrode pattern of the mounting substrate near to the side face of the mounting terminal 76. Accordingly, the connection between the electrode pattern of the mounting substrate and the mounting terminal 76 of the piezoelectric oscillator 70 can be readily confirmed from the outside. Note that, depending on the exemplary embodiment, the side face of the mounting terminal 76 may not be exposed to the side face of the resin package 16.

Then, to the surface of the resin package 16 at the side where the piezoelectric resonator element 18 is mounted, the moisture resistant material 40 which is more excellent in moisture resistance than the molding resin, is applied. Then, after plating is applied to the connection face of the connection terminal 24 and to the mounting face of the mounting terminal 76, the connection-terminal forming lead 22 and the mounting-terminal forming lead 74 are cut off from the frame portion 73 of the lead frame 72. Next, the piezoelectric resonator element 18 is mounted via the conductive material 34 on the connection face of the connection terminal 24. Then, after adjusting the frequency by changing the thickness of the excitation electrode of the piezoelectric resonator element 18, the lid body 44 which hermetic-seals the piezoelectric resonator element 18, is bonded to the resin package 16. Finally, once again, the oscillation frequency of the piezoelectric oscillator 70 is adjusted by the adjustment of the capacitance of the capacitor array mounted in the electronic component 14 or by adjusting the voltage supplied to the variable capacitance diode.

By configuring the piezoelectric oscillator 70 this way, the same effect as that of the piezoelectric oscillator 10 according to the first exemplary embodiment can be attained. In addition, to the above-described piezoelectric oscillator 70, the heat conducting material described in the first exemplary embodiment may be provided.

Moreover, in the above-described piezoelectric oscillator 70, the mounting face of the mounting terminal 76 and the surface of the electronic component 14 exist in the same plane, however, as another exemplary embodiment, the distance of the level difference formed with the inclined portion 80 may be increased, and the surface of the electronic component 14 is covered with the molding resin.

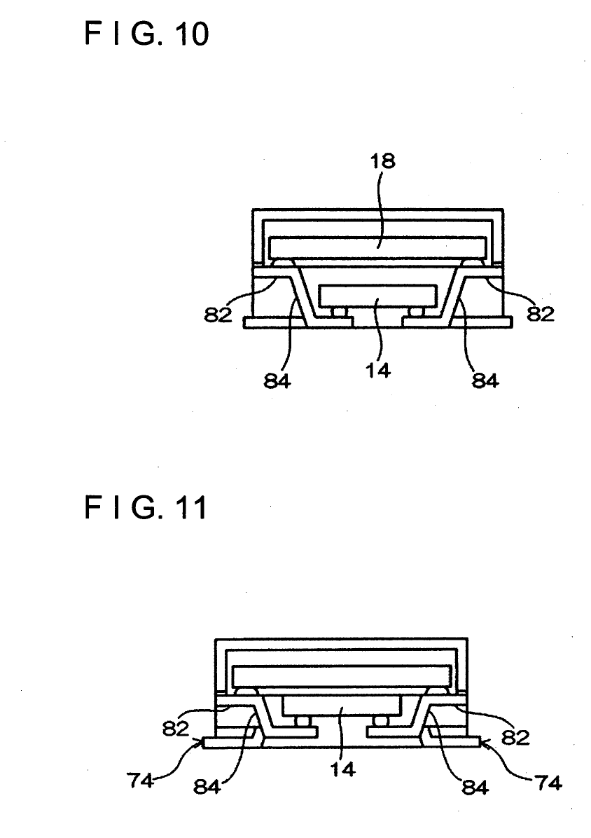

In FIG. 10, there is shown a schematic sectional view of a piezoelectric oscillator that is made bend-forming the connection terminal. The above-described piezoelectric oscillator 70 is configured providing the inclined portion 80 in the mounting-terminal forming lead 74, however, as another exemplary embodiment, the piezoelectric oscillator may be formed providing the inclined portion in the connection terminal. Namely, the piezoelectric oscillator is configured including: the electronic component 14 electrically connected with one side face of a plurality of leads that are formed from a lead frame; a connection terminal 82 connected with a part of the plurality of leads wherein a level difference is formed at the electronic component side; a mold material (a molding resin) that seals the electronic component 14 such that the other side face of the plurality of leads and the mounting face of the connection terminal 82 are exposed; and the piezoelectric resonator element 18 bonded to the connection face of the connection terminal 82 via a conductive material. The level difference is formed with an inclined portion 84 which is a bent lead. Moreover, the connection face of the connection terminal 82 and the surface of the electronic component 14 can be formed in the same face. Furthermore, the lower face of the lead where the electronic component 14 is mounted may be shaved by half-etching or the like, and thereby the lower face of this lead can be covered with the molding resin.

FIG. 11 shows a schematic sectional view of a piezoelectric oscillator wherein a level difference is provided to the mounting-terminal forming lead. As shown in FIG. 11, in order not to cause the lower face of the lead forming the connection terminal 82 to contact with the substrate where the piezoelectric oscillator is mounted, the connection terminal 82 may be formed forming the level difference in the mounting-terminal forming lead 74 in the direction opposite to the inclined portion 84. Consequently, the level difference can be provided between the lower face of the lead, where the electronic component 14 is mounted, and the lower face of the mounting terminal, and thus the lower face of the lead can be covered with the molding resin. If an unwanted terminal is exposed from the molding resin at the time of mounting the piezoelectric oscillator to the mounting substrate, the freedom for wiring of the mounting substrate will be lost. However, in this configuration, because the terminal unwanted for the mounting is covered with a molding resin, the freedom for wiring of the mounting substrate can be improved.

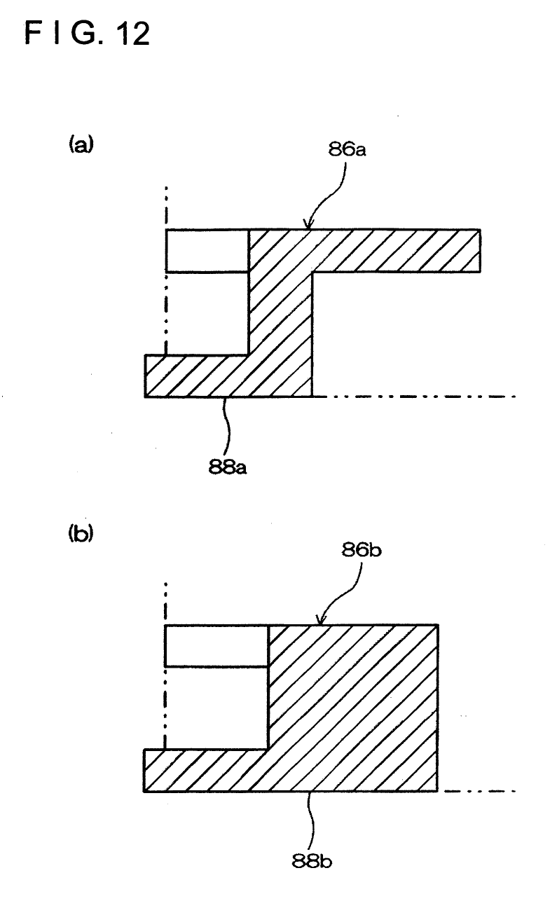

A sectional view of the mounting-terminal forming lead according to an exemplary modification is shown in FIGS. 12(a)-(b). Although in the above-described exemplary embodiment the level difference is formed bending either the mounting-terminal forming lead 74 or the connection-terminal forming lead 22, it may be formed using half-etching. Namely, the lead frame is formed thick in advance, and then the thickness at the upper face side and lower face side of the lead frame are made different by etching, whereby the mounting-terminal forming lead and the connection-terminal forming lead may be formed. Mounting terminal forming leads 86a and 86b can be shaped like the ones shown in FIG. 12 (a) and (b), and mounting terminals 88a and 88b are exposed to the back face of the piezoelectric oscillator. The connection-terminal forming lead can be also similarly shaped. Moreover, the mounting-terminal forming lead and connection-terminal forming lead may be formed changing the thickness of the lead by rolling the lead frame. Accordingly, the size of the piezoelectric oscillator 70 can be made smaller in the width direction.

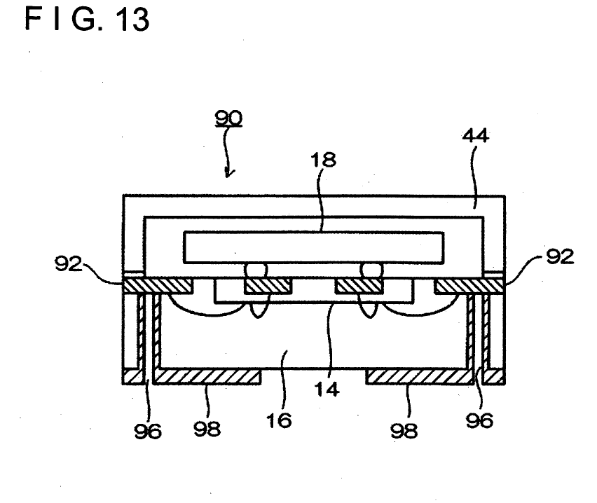

Next, a third exemplary embodiment will be described. In addition, the same numeral is given to the portion having the same configuration as that of the piezoelectric oscillator according to the first exemplary embodiment, and the description thereof will be omitted or simplified. A sectional view of the piezoelectric oscillator according to the third exemplary embodiment is shown in FIG. 13. A piezoelectric oscillator 90 is configured including: the electronic component 14 arranged in a space used for arrangement of the electronic component of the lead frame and electrically connected with one side face of a plurality of leads 92 that is formed from the lead frame; a mold material (a molding resin) that seals the electronic component 14 such that the other side face of the plurality of leads 92 is exposed; a piezoelectric resonator element bonded to the other side face side of a connection terminal 93 that is formed in a part of the plurality of leads 92 via a conductive material. Moreover, a mounting terminal 98 is provided in the back face of the molding resin, and wiring is provided in a hole 96 (a via hole or a through-hole) that penetrates through this molding resin from up to down, whereby the mounting terminal 98 and the lead 92 are conducting.

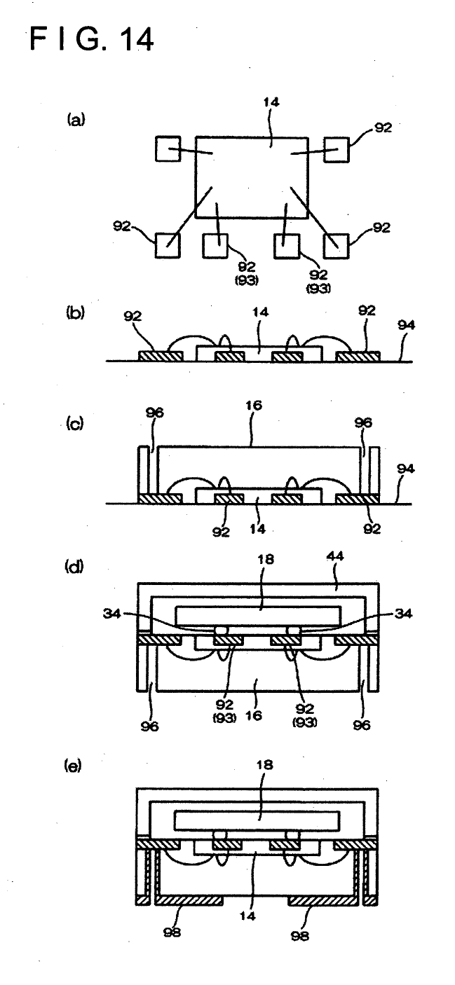

FIGS. 14(a)-(e) are schematics showing the manufacturing of the piezoelectric oscillator 90. FIG. 14 (a) is a plane view, and FIG. 14 (b)-(e) are sectional views. The manufacturing of the piezoelectric oscillator 90 is carried out as follows. First, a lead frame where the plurality of leads 92 is formed, and the electronic component 14 are mounted on a tape sheet 94. At this time, the electronic component 14 is arranged in a space used for arrangement of the electronic component in the lead frame. Then, wire bonding is applied to the electrode provided in the electronic component 14 and to the lead 92, thereby making electrical connection (refer to FIGS. 14 (a) and (b)). In addition, the electrical connection may be made by flip-chip bonding. Then, the electronic component 14 and the lead 92 are sealed with a molding resin to form the resin package 16 (refer to FIG. 14 (c)). At this time, the side, where the wire bonding is applied to the electronic component 14 and lead 92, is sealed with a molding resin, and the resin package 16 is not formed on the side where the tape sheet 94 is stuck. Moreover, there are provided at least two holes 96 that penetrate through the resin package 16 in the vertical direction from the surface of the leads 92. This hole 96 is formed by providing a protrusion in the resin mold tooling in advance. Namely, when the electronic component 14 and lead 92 are put into the resin molding tooling, the tip of the protrusion provided in this tooling is caused to contact with the surface of the lead 92, and then the molding resin is injected into the tooling, and thereby the hole 96 is formed. In addition, the penetrating hole 96 may be formed by a laser or by etching after sealing with the molding resin.

Then, the tape sheet 94 is removed from the resin package 16, and the resin package 16 is turned upside down. Then, the piezoelectric resonator element 18 is mounted to the connection terminal 93 via the conductive material 34. Moreover, a moisture resistant material may be applied to the surface of the resin package 16 at the side where the piezoelectric resonator element 18 is mounted. Then, after having adjusted the frequency by changing the thickness of the excitation electrode provided in the piezoelectric resonator element 18, the lid body 44 hermetic-sealing the piezoelectric resonator element 18, is bonded to the resin package 16 via a soldering material (refer to FIG. 14 (d)).

Then, plating is applied to the hole 96 that is formed in the resin package 16, and to the back face of the resin package 16 (the piezoelectric oscillator 90), thereby forming the mounting terminal 98 that is electrically connected with the lead 92 in the back face of the resin package 16 (refer to FIG. 14 (e)). In addition, the process to apply the plating may be carried out before the piezoelectric resonator element 18 is mounted to the connection terminal.

Finally, the oscillation frequency of the piezoelectric oscillator 90 is adjusted once again by the adjustment of the capacitance of the capacitor array mounted in the electronic component 14 and by adjusting the voltage supplied to the variable capacitance diode. Thus, the piezoelectric oscillator 90 is manufactured.

By configuring the piezoelectric oscillator 90 this way, the same effect as that of the piezoelectric oscillator 10 according to the first exemplary embodiment can be attained. In addition, to the above-described piezoelectric oscillator 90, the heat conducting material described in the first exemplary embodiment may be provided.

Moreover, the mounting terminal 98 can be formed using the whole rear-face of the resin package 16. Namely, because the back face of the piezoelectric oscillator 90 consists of only the resin package 16, and the electronic component 14 or the like is not exposed, the mounting terminal 98 and the electronic component 14 can be arranged in piles above and below. Consequently, the mounting terminal 98 can be formed large and thus the joining strength between the mounting terminal 98 and the mounting substrate can be enhanced.

Moreover, in the piezoelectric oscillator 90 according to the third exemplary embodiment, because the mounting terminal 98 and the lead 92 conduct penetrating through the resin package 16 in the vertical direction, the lead frame can be reduced in size by the amount of bending as compared with the case where the lead frame is bent to conduct the mounting terminal 98 and the electronic component 14.

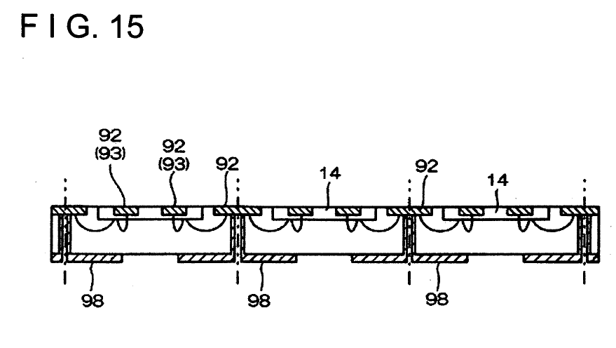

FIG. 15 is a schematic showing another exemplary embodiment of the manufacturing of the piezoelectric oscillator. A plurality of piezoelectric oscillators 90 according to the third exemplary embodiment can be arranged and formed in the order in the plane direction, and manufactured singulating them by dicing. In addition, the dicing position is shown by the two-dot broken line in FIG. 15. In this case, in addition to the exemplary embodiment wherein the hole 96 (a through-hole or a via hole) is provided in the resin package 16 to conduct the lead 92 and the mounting terminal 98, castellation may be provided to the side face of the resin package 16 to conduct the lead 92 and the mounting terminal 98. Moreover, in this exemplary embodiment, before mounting the piezoelectric resonator element to the resin package, the mounting terminal 98 is formed.

In addition, in the piezoelectric oscillator 90 according to the third exemplary embodiment, the mounting terminal and the connection terminal may be formed reversely. That is, the mounting terminal 98 may be formed from the lead 92, and the connection terminal may be formed connecting with the lead 92 via a hole.

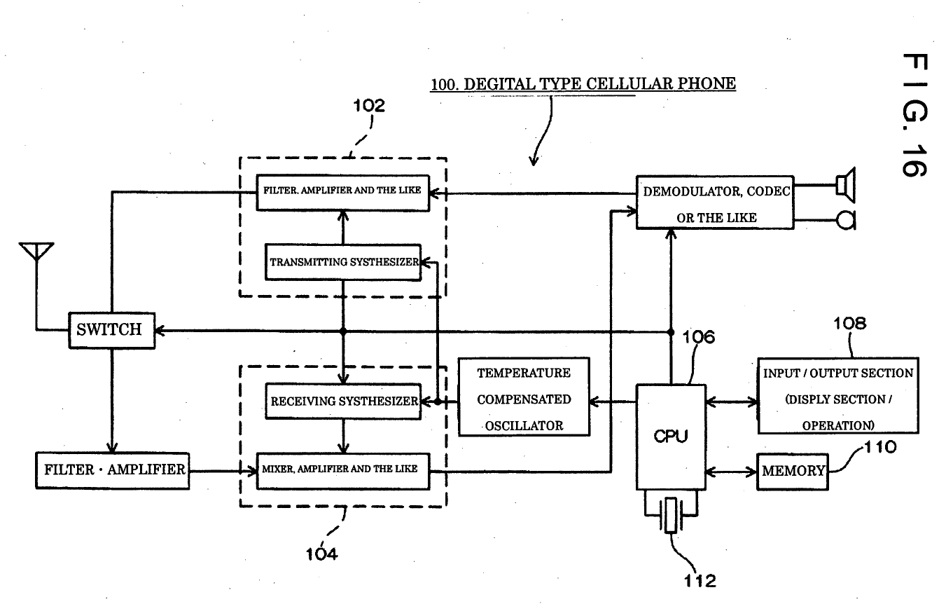

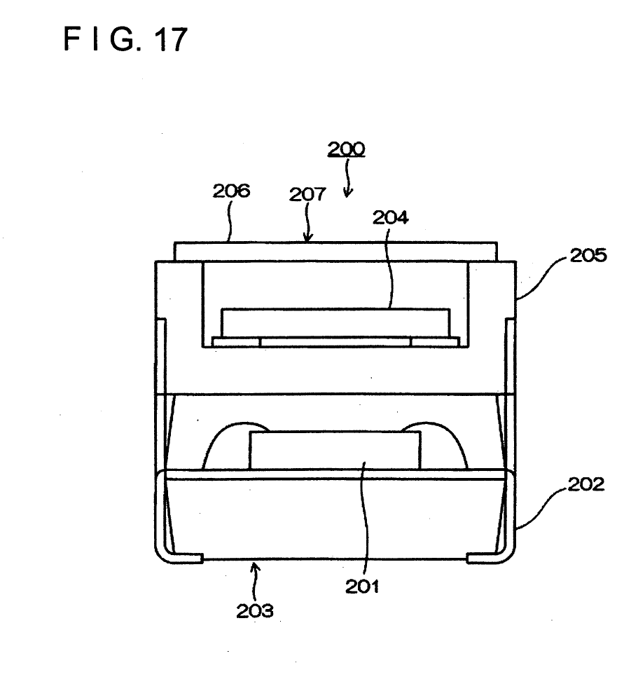

Next, a fourth exemplary embodiment will be described. In the fourth exemplary embodiment, one example, wherein the piezoelectric oscillators 10, 70, and 90 described in the first to third exemplary embodiments is mounted in electronic devices, will be described. In FIG. 16, a schematic block diagram of a digital cellular phone is shown. A digital cellular phone 100 includes a transmitting section 102 and a receiver section 104 or the like for transmitting/receiving signals, and to these transmitting section 102 and receiver section 104, a central processing unit (CPU) 106 to control these is connected. Moreover, the CPU 106 controls an information input/output section 108 including a display section, an operation key for inputting information, or the like, and a memory 110 formed of RAM, ROM, and the like, other than controlling the modulation and demodulation of the transmitting/receiving signals. For this reason, a piezoelectric device 112 is mounted in the CPU 106, and the output frequency thereof is used as the clock signal adapted to the contents of the control by a predetermined frequency divider (not shown) or the like that is built in the CPU 106.

The application of the piezoelectric oscillators 10, 70, and 90 according to the exemplary embodiments of the present invention includes a temperature compensated crystal oscillator (TCXO), for example. This TCXO is a piezoelectric oscillator wherein frequency change due to ambient temperature change is made small, and is widely used as a frequency reference source for the receiver and transmitting sections. Demand for reduction in size of the TCXO has increased along with the reduction in size of cellular-phone devices, and the reduction in size of the piezoelectric oscillator according to the exemplary embodiments of the present invention is extremely advantageous. Also, the piezoelectric oscillator according to the exemplary embodiments of the present invention can be applied to a real-time clock to provide date-time information to a cellular-phone device that includes a CPU, for example.

Moreover, the piezoelectric oscillators 10, 70, and 90 according to the exemplary embodiments of the present invention can be applied not only to the above-described digital cellular-phone device, but also to electronic devices that obtain control clock signals from piezoelectric oscillators, such as personal computers, workstations, PDAs (Personal Digital (Data) Assistants: a personal information terminal), and the like. In this way, using the piezoelectric oscillator according to the above-described embodiments as electronic devices realizes electronic devices to be smaller in size and having high reliability.

1. A piezoelectric oscillator, comprising:
a lead frame including a plurality of leads;
an electronic component electrically connected with one side face of the plurality of leads;
a mold material that seals the electronic component such that an other side face of the plurality of leads is exposed;
a piezoelectric resonator element bonded to the other side face of the plurality of leads via a conductive material; and
a lid body that hermetic-seals the piezoelectric resonator element.

2. A piezoelectric oscillator, comprising:
a lead frame including a plurality of leads;
an electronic component electrically connected with one side face of the plurality of leads;
a plurality of mounting terminals connected with a part of the plurality of leads, a level difference being formed on the electronic component side,
a mold material that seals the electronic component such that an other side face of the plurality of leads and a mounting face of the plurality of mounting terminals are exposed;
a piezoelectric resonator element bonded to the other side face of the lead via a conductive material; and
a lid body that hermetic-seals the piezoelectric resonator element.

3. The piezoelectric oscillator according to claim 2, the mounting face of the mounting terminal and a surface of the electronic component being in the same face.

4. A piezoelectric oscillator, comprising:
a lead frame including a plurality of leads;
an electronic component electrically connected with one side face of the plurality of leads;
a connection terminal connected with a part of the plurality of leads, a level difference being formed on the electronic component side;
a mold material that seals the electronic component such that an other side face of the plurality of leads and a connection face of the connection terminal are exposed;
a piezoelectric resonator element bonded to the connection face of the connection terminal via a conductive material; and
a lid body that hermetic-seals the piezoelectric resonator element.

5. The piezoelectric oscillator according to claim 4, the connection face of the connection terminal and a surface of the electronic component being in the same face.

6. The piezoelectric oscillator according to claim 1, the electrical connection of the electronic component with the lead being carried out by flip-chip bonding.

7. A piezoelectric oscillator, comprising:
a lead frame including a plurality of leads;
an electronic component arranged in a space used to arrange the electronic component in the lead frame and electrically connected with one side face of the plurality of leads;
a mold material that seals the electronic component such that an other side face of the plurality of leads is exposed;
a piezoelectric resonator element bonded to the other side face side of the plurality of leads via a conductive material; and
a lid body that hermetic-seals the piezoelectric resonator element.

8. A piezoelectric oscillator, comprising:
a lead frame including a plurality of leads;
an electronic component electrically connected with one side face of the plurality of leads;
a mold material that seals the electronic component such that an other side face of the plurality of leads is exposed;
a piezoelectric resonator element bonded to the other side face of the plurality of leads via a conductive material;
a mounting terminal electrically connected via wiring that is formed in a hole, the hole provided in a part of the mold material; and
a lid body that hermetic-seals the piezoelectric resonator element.

9. The piezoelectric oscillator according to claim 1, a moisture resistant material being applied to a surface of the mold material, the surface facing to the side where the piezoelectric resonator element is mounted.

10. The piezoelectric oscillator according to claim 1, a heat conducting material being provided in between the electronic component and the piezoelectric resonator element.

11. An electronic device, comprising:
the piezoelectric oscillator according to claim 1.
